(19) United States
(12) Patent Application Publication
(10) Pub. No.: US 2007/0133320 A1
(43) Pub. Date: Jun. 14, 2007

(54) Circuit and method of boosting voltage for a semiconductor memory device

(75) Inventors: Young-Sun Min, Seoul (KR); Jong-Hyun Choi, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/634,599

(22) Filed: Dec. 6, 2006

(30) Foreign Application Priority Data
Dec. 13, 2005 (KR) 10-2005-0122240

(51) Int. Cl. G11C 7/00

(52) U.S. Cl. 365/189.11

(57) ABSTRACT

A voltage boosting circuit of a semiconductor memory device for decreasing power consumption can include a first precharge circuit, a second precharge circuit, a first capacitive element, a second capacitive element and a coupling circuit. The first precharge circuit precharges a first node using a first supply voltage and the second precharge circuit precharges a second node using a second supply voltage. The first capacitive element boosts a voltage level of the first node in response to a first pulse signal and the second capacitive element boosts a voltage level of the second node in response to a second pulse signal. The coupling circuit electrically couples the first node to the second node in response to a boosting enable signal and a self-refresh control signal.

### CROSS-REFERENCE TO RELATED APPLICATIONS

This application claims priority under 35 USC § 119 to Korean Patent Application No. 10-2005-122240, filed on Dec. 13, 2005 in the Korean Intellectual Property Office (KIPO), the contents of which are herein incorporated by reference in their entirety.

### BACKGROUND OF THE INVENTION

1. Field of the Invention

The present invention relates to a semiconductor memory device, and more particularly to a voltage boosting circuit of a semiconductor memory device.

2. Description of the Related Art

FIG. 1 is a circuit diagram illustrating an example of a conventional voltage boosting circuit of a semiconductor memory device. The conventional voltage boosting circuit of FIG. 1 is disclosed in Korean Patent Laid-Open Publication No. 2005-44086.

Referring to FIG. 1, the voltage boosting circuit 100 includes a first capacitor 102, a second capacitor 104, a precharge circuit 106, a delay circuit 108 and a transfer circuit 110. A first pulse P1 is a signal that swings between a supply voltage VCC and a ground voltage. A second pulse P2 is a signal for controlling an N-type metal-oxide semiconductor (NMOS) transistor 112 used for coupling a node N3 and a node N4. The transfer circuit 110 provides a voltage of the node N4 as a boosted voltage VPP in response to a third pulse P3. The precharge circuit 106 precharges the node N3 and the node N4 to a supply voltage level VCC in response to a fourth pulse P4.

When the second pulse P2 and the third pulse P3 are at a logic “low” and the fourth pulse P4 is at a logic “high,” the node N3 and the node N4 are precharged to the supply voltage level VCC. When the fourth pulse P4 is changed to a logic “low” and the first pulse P1 is applied to the voltage boosting circuit 100, a voltage level of the node N3 becomes 2 VCC. When the second pulse P2 is changed to a logic “high,” the NMOS transistor 112 is turned on, the node N3 and the node N4 are electrically connected to each other and voltage levels of the node N3 and the node N4 become 1.5 VCC. When the first pulse P1 is transferred to a node N2 through the delay circuit 108 and the second pulse P2 is a logic “low,” the node N3 and the node N4 are electrically disconnected, a voltage level of the node N2 is VCC and a voltage level of the node N4 become 2.5 VCC. When the third pulse P3 is changed to a logic “high,” a voltage level of the node N4, that is, 2.5 VCC, is outputted as the boosted voltage VPP.

As shown in FIG. 1, the node N3 and the node N4 are electrically coupled through the NMOS transistor 112, irrespective of an operating mode of a semiconductor memory device, so that power consumption can be unnecessarily increased. A period in which the boosted voltage VPP is generated in a self-refresh mode can be longer than a period in which the boosted voltage VPP is generated in a normal mode.

Therefore, a voltage boosting circuit is needed, in which a time for charges to be shared between boosting nodes in the normal mode is different from a time for charges to be shared between boosting nodes in the self-refresh mode.

### SUMMARY OF THE INVENTION

In accordance with various aspects of the present invention, provided is a voltage boosting circuit in which consumption of a boosted voltage can be decreased.

In accordance with various aspects of the present invention, also provided is a method of boosting voltage in which consumption of a boosted voltage can be decreased.

In accordance with one aspect of the present invention, a voltage boosting circuit of a semiconductor memory device includes a first precharge circuit, a second precharge circuit, a first capacitive element, a second capacitive element and a coupling circuit. The first precharge circuit can be configured to precharge a first node by using a first supply voltage. The second precharge circuit can be configured to precharge a second node by using a second supply voltage. The first capacitive element can be configured to boost a voltage level of the first node in response to a first pulse signal. The second capacitive element can be configured to boost a voltage level of the second node in response to a second pulse signal. The coupling circuit can be configured to electrically couple the first node to the second node in response to a boosting enable signal and a self-refresh control signal.

A boosted voltage is output at the second node output, and when the first node is electrically coupled to the second node, a time during which the voltage level of the second node becomes substantially the same as the voltage level of the first node in a self-refresh mode is longer than a time during which the voltage level of the second node becomes substantially the same as the voltage level of the first node in a normal mode.

The first supply voltage and the second supply voltage can be substantially identical.

The first supply voltage and the second supply voltage can be applied from a source external to the semiconductor memory device.

The coupling circuit can include: a third precharge circuit configured to precharge a third node using a third supply voltage; a fourth precharge circuit configured to precharge a fourth node using a fourth supply voltage; a control signal generating circuit configured to generate a first control signal and a second control signal in response to the boosting enable signal and the self-refresh control signal, and to provide the first control signal to a fifth node and the second control signal to a sixth node; a third capacitive element configured to boost a voltage level of the third node in response to the first control signal; a fourth capacitive element configured to boost a voltage level of the fourth node in response to the second control signal; a first transistor configured to electrically couple the first node and the second node in response to the voltage of the third node; and a second transistor configured to electrically couple the first node and the second node in response to the voltage of the fourth node.

The first transistor can be configured to turn on in the normal mode and the second transistor can be configured to turn on in the normal mode and the self-refresh mode.

A size of the first transistor can be larger than a size of the second transistor.

A size of the third capacitor can be larger than a size of the fourth capacitor.

The coupling circuit can be configured to boost the voltage level of the third node and the voltage level of the fourth node using a fifth supply voltage, which is lower than the boosted voltage, and then to boost the voltage level of the third node and the voltage level of the fourth node using the boosted voltage.

The control signal generating circuit can include: a first control circuit configured to generate the first control signal in response to the boosting enable signal and the self-refresh control signal; and a second control circuit configured to generate the second control signal in response to the boosting enable signal.

The first control circuit can include: a NAND gate configured to perform a NAND operation with respect to the boosting enable signal and the self-refresh control signal; a first delay circuit configured to delay an output signal of the NAND gate for a predetermined time; a first metal-oxide semiconductor (MOS) transistor configured to provide the boosted voltage to the fifth node in response to an output signal of the first delay circuit; and a first inverter configured to be driven by the fifth supply voltage and invert the output signal of the NAND gate to be provided to the fifth node.

The first inverter can include: a first P-type MOS (PMOS) transistor having a gate connected to the output terminal of the NAND gate, a source connected to the fifth supply voltage, and a drain connected to the fifth node; and a first N-type MOS (NMOS) transistor having a gate connected to the output terminal of the NAND gate, a source connected to a ground voltage, and a drain connected to the fifth node.

In an alternative form, the first inverter can include: a first NMOS transistor having a drain connected to the fifth supply voltage and a gate connected to an output terminal of the first delay circuit; a first PMOS transistor having a gate connected to the output terminal of the NAND gate, a source connected to a source of the first NMOS transistor, and a drain connected to the fifth node; and a second NMOS transistor having a gate connected to the output terminal of the NAND gate, a source connected to the ground voltage, and a drain connected to the fifth node.

In another alternative form, the first inverter can include: a first NMOS transistor having a drain connected to the fifth supply voltage and a gate connected to an output terminal of the first delay circuit; a first PMOS transistor having a gate connected to the output terminal of the NAND gate, a source connected to a source of the first NMOS transistor, and a drain connected to the fifth node; a second NMOS transistor having a drain connected to the fifth node and a gate receiving the boosted voltage; and a third NMOS transistor having a gate connected to the output terminal of the NAND gate, a source connected to the ground voltage, and a drain connected to a source of the second NMOS transistor.

The second control circuit can include: a first inverter configured to invert the boosting enable signal; a first delay circuit connected to an output terminal of the first inverter and configured to delay an output signal of the first inverter for a predetermined time; a MOS transistor configured to provide the boosted voltage to the sixth node in response to an output signal of the first delay circuit; and a second inverter configured to be driven by the fifth supply voltage and invert an output signal of the first inverter to be provided to the sixth node.

The second inverter can include: a first PMOS transistor having a gate connected to the output terminal of the first inverter, a source connected to the fifth supply voltage, and a drain connected to the sixth node; and a first NMOS transistor having a gate connected to the output terminal of the first inverter, a source connected to the ground voltage, and a drain connected to the sixth node.

In an alternative form, the second inverter can comprise: a first NMOS transistor having a drain connected to the fifth supply voltage and a gate connected to an output terminal of the first delay circuit; a first PMOS transistor having a gate connected to the output terminal of the first inverter, a source connected to the first NMOS transistor, and a drain connected to the sixth node; and a second NMOS transistor having a gate connected to the output terminal of the first inverter, a source connected to the ground voltage, and a drain connected to the sixth node.

In another alternative form, the second inverter can comprise: a first NMOS transistor having a drain connected to the fifth supply voltage and a gate connected to an output terminal of the first delay circuit; a first PMOS transistor having a gate connected to the output terminal of the first inverter, a source connected to a source of the first NMOS transistor, and a drain connected to the sixth node; a second NMOS transistor having a drain connected to the sixth node and a gate receiving the boosted voltage; and a third NMOS transistor having a gate connected to the output terminal of the first inverter, a source connected to the ground voltage, and a drain connected to a source of the second NMOS transistor.

The voltage boosting circuit of a semiconductor memory device can further include a transfer circuit configured to transfer the boosted voltage to circuit blocks of the semiconductor memory device.

In accordance with another aspect of the present invention, provided is a method of boosting the voltage of a semiconductor memory device. The method comprises: precharging a first node using a first supply voltage; precharging a second node using a second supply voltage; boosting a voltage level of the first node in response to a first pulse signal; electrically coupling the first node to the second node in response to a boosting enable signal and a self-refresh control signal; and boosting a voltage level of the second node in response to a second pulse signal.

When the first node is electrically coupled to the second node, the method can further include causing a time during which the voltage level of the second node becomes substantially the same as the voltage level of the first node in a self-refresh mode to be longer than a time during which the voltage level of the second node becomes substantially the same as the voltage level of the first node in a normal mode.

Therefore, in accordance with various aspects of the present invention, the voltage boosting circuit of a semiconductor memory device can include a coupling circuit configured to electrically couple boosting nodes to decrease power consumption by causing the time for charges to be shared between the boosting nodes to be different in accordance with the operating mode.

### BRIEF DESCRIPTION OF THE DRAWINGS

Various aspects of the invention will become more apparent in view of the attached drawing figures, which are provided by way of example, not by way of limitation, in which

FIG. 1 is a circuit diagram illustrating an example of a conventional voltage boosting circuit of a semiconductor memory device.

FIG. 2 is a circuit diagram illustrating an example embodiment of a voltage boosting circuit according to the present invention.

FIG. 3 is a circuit diagram illustrating an example embodiment of a coupling circuit included in the voltage boosting circuit in FIG. 2.

FIG. 4 is a circuit diagram illustrating an example embodiment of a control signal generating circuit included in the coupling circuit in FIG. 3.

FIG. 5 illustrates a waveform a control signal generated by the control signal generating circuit in FIG. 4.

FIG. 6 is a circuit diagram illustrating an example embodiment of a control signal generating circuit included in the coupling circuit in FIG. 3.

FIG. 7 is a circuit diagram illustrating another example embodiment of a control signal generating circuit included in the coupling circuit in FIG. 3.

### DESCRIPTION OF THE EMBODIMENTS

Detailed illustrative embodiments in accordance with the present invention are disclosed herein. However, specific structural and functional details disclosed herein are merely representative for purposes of describing example embodiments. This invention can, however, be embodied in many alternate forms and should not be construed as limited to the embodiments set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

It will be understood that, although the terms first, second, etc. can be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

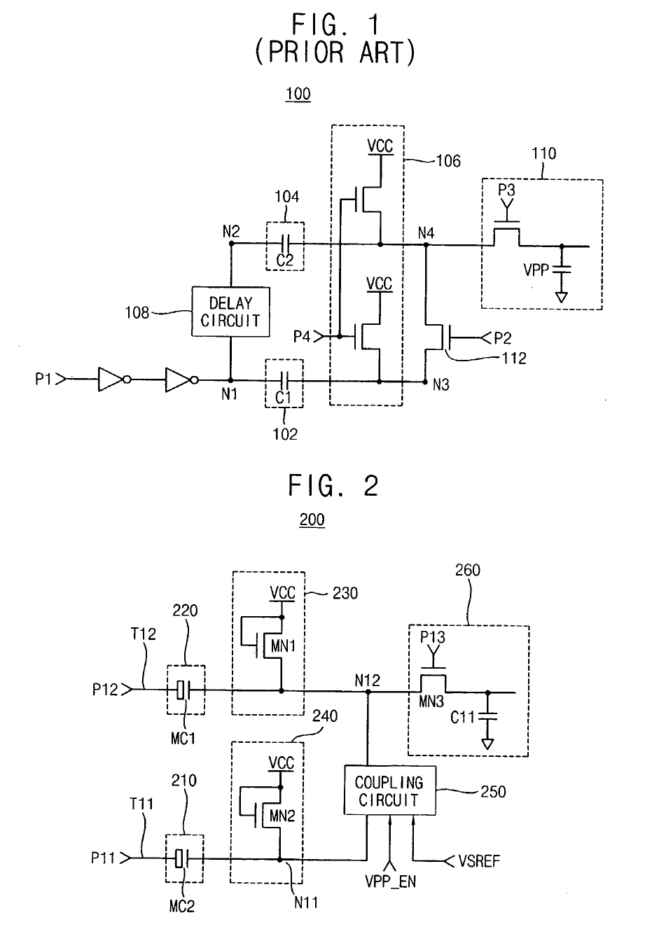

FIG. 2 is a circuit diagram illustrating an example embodiment of a voltage boosting circuit of a semiconductor memory device. Referring to FIG. 2, the voltage boosting circuit 200 can include precharge circuits 230 and 240, capacitors 210 and 220, and a coupling circuit 250. The capacitors 210 and 220 can each include metal-oxide semiconductor (MOS) capacitors. The precharge circuit 230 can include a diode-connected N-type MOS (NMOS) transistor MN1 and the precharge circuit 240 can include a diode-connected NMOS transistor MN2, as examples.

The precharge circuit 240 precharges a node N11 using a supply voltage VCC and the precharge circuit 230 precharges a node N12 also using the supply voltage VCC. The capacitor MC2 boosts a voltage level of the node N11 in response to a pulse signal P11, and the capacitor MC1 boosts a voltage level of the node N12 in response to a pulse signal P12. The coupling circuit 250 couples the node N11 to the node N12 in response to a boosting enable signal VP_EN and a self-refresh control signal VSREF. A boosted voltage VPP is output at the node N12.

In the voltage boosting circuit 200, when the node N11 is electrically coupled to the node N12, a time during which the voltage level of the node N12 becomes substantially the same as the voltage level of the node N11 in a self-refresh mode can be longer than a time during which the voltage level of the node N12 becomes substantially the same as the voltage level of the node N11 in a normal mode.

The voltage boosting circuit 200 can further include a transfer circuit 260 configured to transfer a signal of the node N12 to an external circuit block in response to a pulse signal P13. The transfer circuit 260 can include an NMOS transistor MN3 and a capacitor C11.

The operation of the voltage boosting circuit 200 of a semiconductor memory device according to the example embodiment shown in FIG. 2 will be described, as follows.

Pulse signals P11, P12 and P13 can be signals that swing between 0 V and the supply voltage VCC, respectively.

The voltage boosting circuit 200 in FIG. 2 has a double-boosting structure. First, the voltage level of the node N11 is precharged to VCC-Vth by the precharge circuit 240 and the voltage level of the node N12 is precharged to VCC-Vth by the precharge circuit 230. Vth indicates a threshold voltage of a MOS transistor and VCC-Vth is VCC minus Vth.

Next, the voltage level of the node N11 is boosted by the capacitor MC2 in response to the pulse signal P11. In the voltage boosting operation, the voltage level of the pulse signal P11 is VCC. For example, when the supply voltage VCC is 3.0 V and Vth is 0.5 V, the voltage level of the node N11 is about 5.5 V (=3.0 V−0.5 V+3.0 V) and the voltage level of the node N12 is about 2.5 V (=3.0 V−0.5 V).

After a charge sharing operation including electrical coupling of the node N11 to the node N12 by the coupling circuit 250, the voltage levels of the node N11 and the node N12 become about 4.0 V (=(5.5 V+2.5 V)/2), respectively.

The voltage of the node N12 is boosted by the capacitor MC1 in response to the pulse signal P12. In the voltage boosting operation, the voltage level of the pulse signal P12 is VCC. For example, when the supply voltage VCC is 3.0 V and Vth is 0.5 V, the voltage level of the node N12 is about 7.0 V (=4.0 V+3.0 V).

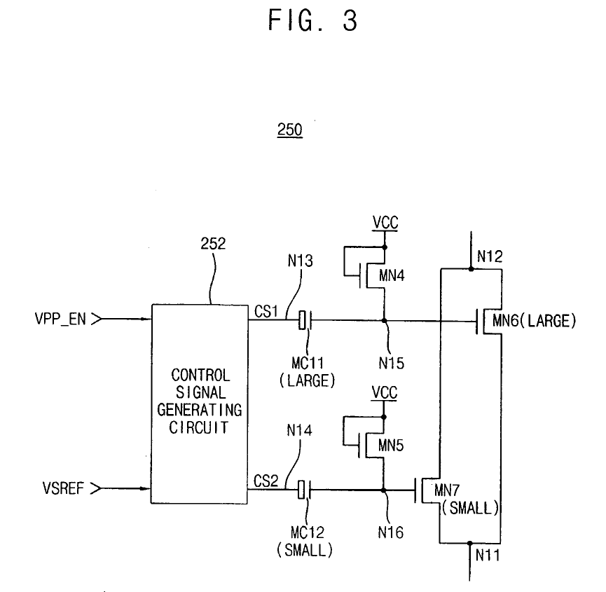

The coupling circuit 250 can include transistors MN6 and MN7 in FIG. 3 configured to electrically couple the node N11 and the node N12. The boosted voltage level of the node N11 is 5.5 V, so that a voltage level of more than about 5.5 V+Vth should be applied to gates of the transistors MN6 and MN7 in FIG. 3 included in the coupling circuit 250, respectively, for electrically coupling the node N11 and the node N12.

The coupling circuit 250 couples the node N11 to the node N12 in response to the boosting enable signal VPP_EN and the self-refresh control signal VSREF.

In the voltage boosting circuit in FIG. 2, a boosted voltage should be generated every about 80 ns in the normal mode and every about 140 ns in the self-refresh mode. When the node N11 and the node N12 are electrically coupled, a time during which the voltage level of the node N12 becomes substantially the same as the voltage level of the node N11 in the self-refresh mode is longer than a time during which the voltage level of the node N12 becomes substantially the same as the voltage level of the node N11 in the normal mode. Namely, a time for charges to be shared between the node N11 and the node N12 in the self-refresh mode is longer than a time for charges to be shared between the node N11 and the node N12 in the normal mode.

A signal of the node N12 can be transferred to the external circuit block through the transfer circuit 260.

FIG. 3 is a circuit diagram illustrating an example embodiment of the coupling circuit 250 included in the voltage boosting circuit in FIG. 2. Referring to FIG. 3, the coupling circuit 250 can include precharge circuits MN4 and MN5, a control signal generating circuit 252, capacitors MC11 and MC12 and transistors MN6 and MN7. The capacitors MC11 and MC12 can each include MOS capacitors.

The precharge circuit MN4 and the precharge circuit MN5 can each include diode-connected NMOS transistors. The precharge circuit MN4 precharges a node N15 using the supply voltage VCC and the precharge circuit MN5 precharges a node N16 using the supply voltage VCC.

The control signal generating circuit 252 generates a first control signal CS1 and a second control signal CS2 in response to the boosting enable signal VPP_EN and the self-refresh control signal VSREF, and provides the first control signal CS1 to a node N13 and the second control signal CS2 to a node N14.

The capacitor MC11 boosts a voltage level of the node N15 in response to the first control signal CS1, and the capacitor MC12 boosts a voltage level of the node N16 in response to the second control signal CS2.

The transistor MN6 electrically couples the node N11 and the node N12 in response to the voltage level of the node N15 and the transistor MN7 electrically couples the node N11 and the node N12 in response to the voltage level of the node N16.

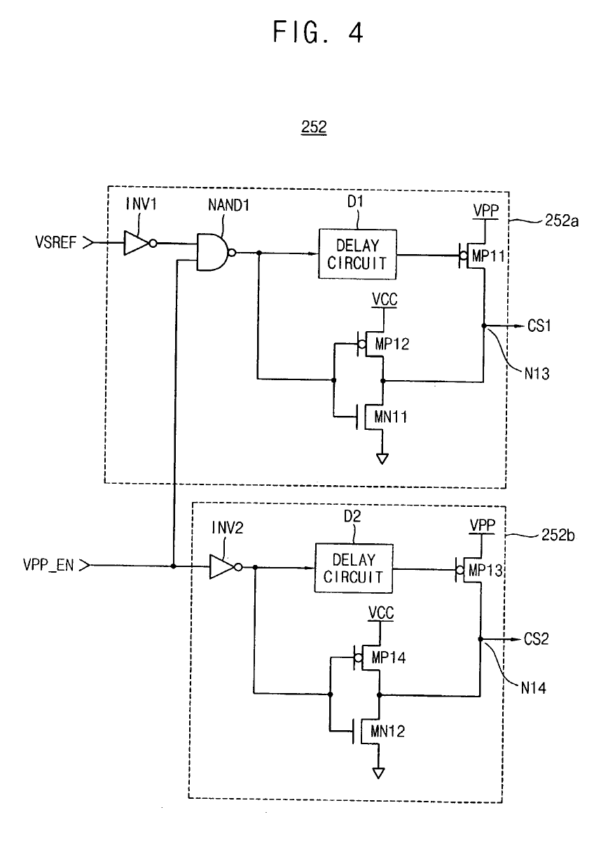

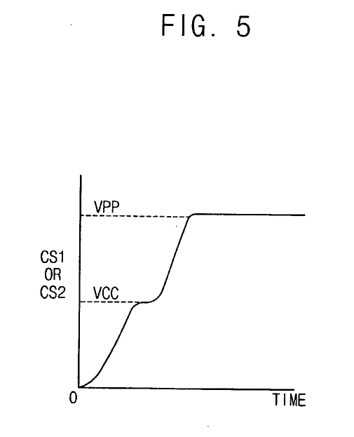

FIG. 4 is a circuit diagram illustrating an example embodiment of the control signal generating circuit 252 included in the coupling circuit 250 in FIG. 3. Referring to FIG. 4, a control signal generating circuit 252 can include control circuits 252a and 252b.

The control circuit 252a can include an inverter INV1, a NAND gate NAND1, a delay circuit D1, a P-type MOS (PMOS) transistor MP11, a PMOS transistor MP12 and an NMOS transistor MN11. The PMOS transistor MP12 and the NMOS transistor MN11 can form an inverter.

The inverter INV1 inverts the self-refresh signal VSREF. The NAND gate NAND1 performs a NAND operation with respect to the boosting enable signal VPP_EN and an output signal of the inverter INV1. The delay circuit D1 delays an output signal of the NAND gate NAND1 for a predetermined time. The PMOS transistor MP11 provides the boosted voltage VPP to the node N13 in response to an output signal of the delay circuit D1. The inverter formed by the PMOS transistor MP12 and the NMOS transistor MN11 is driven by the supply voltage VCC and inverts the output signal of the NAND gate NAND1 to be provided to the node N13.

The control circuit 252b can include an inverter INV2, a delay circuit D2, a PMOS transistor MP13, a PMOS transistor MP14 and an NMOS transistor MN12. The PMOS transistor MP14 and the NMOS transistor MN12 form an inverter.

The inverter INV2 inverts the boosting enable signal VPP_EN. The delay circuit D2 delays an output signal of the inverter INV2 for a predetermined time. The PMOS transistor MP13 provides the boosted voltage VPP to the node N14 in response to an output signal of the delay circuit D2. The inverter formed by the PMOS transistor MP14 and the NMOS transistor MN12 is driven by the supply voltage VCC and inverts the output signal of the inverter INV2 to be provided to the node N14.

FIG. 5 illustrates a waveform of one of control signals from the control signal generating circuit in FIG. 4. The operation of the coupling circuit 250 included in the voltage boosting circuit in FIG. 2 will be described as follows with reference to FIG. 3 through FIG. 5.

Referring to FIG. 3, the control signal generating circuit 252 generates the first control signal CS1 and the second control signal CS2 in response to the boosting enable signal VPP_EN and the self-refresh control signal VSREF. The node N15 is precharged by the precharge circuit MN4 and the node N16 is precharged by the precharge circuit MN5.

The voltage level of the node N15 is boosted by the capacitor MC11 in response to the first control signal CS1 and the voltage level of the node N16 is boosted by the capacitor MC12 in response to the second control signal CS2.

Referring to FIG. 4, the first control circuit 252a generates the first control signal CS1 in response to the boosting enable signal VPP_EN and the self-refresh signal VSREF and the second control circuit 252b generates the second control signal CS2 in response to the boosting enable signal VPP_EN. When the boosting enable signal VPP_EN is a logic “high” and the self-refresh signal VSREF is a logic “low,” which occurs only in the normal mode, the first control signal CS1 is a logic “high.” When the self-refresh signal VSREF is a logic “high,” which occurs in the self-refresh mode, the first control signal CS1 is a logic “low.” When the boosting enable signal VPP_EN is a logic “high,” the second control signal CS2 is a logic “high.”

In the control signal generating circuit 252 in FIG. 4, only the second control signal CS2 is a logic “high” in the self-refresh mode, but both the first control signal CS1 and the second control signal CS2 are logic “high” in the normal mode. That is, in the control signal generating circuit 252 in FIG. 4, only the second control signal CS2 is enabled in the self-refresh mode, but both the first control signal CS1 and the second control signal CS2 are enabled in the normal mode.

Therefore, only the NMOS transistor MN7 included in the coupling circuit 250 in FIG. 3 is turned on in the self-refresh mode, but both the NMOS transistor MN6 and the NMOS transistor MN7 included in the coupling circuit 250 in FIG. 3 are turned on in the normal mode.

In the self-refresh mode, a period for accessing memory cell arrays is longer than a period for accessing memory cell arrays in the normal mode, so that a period for generating the boosted voltage VPP can be longer than a period for generating the boosted voltage VPP in the normal mode. Therefore, a time during which the coupling circuit 250 in FIG. 2 electrically couples the node N11 and the node N12 to share charges between the node N11 and the node N12 in the self-refresh mode can be longer than a time during which the coupling circuit 250 in FIG. 2 electrically couples the node N11 and the node N12 to share charges between the node N11 and the node N12 in the normal mode.

Referring now to FIG. 4, the first control circuit 252a can include the inverter formed by the PMOS transistor MP12 and the NMOS transistor MN11, and the delay circuit D1. When the first control signal CS1 is changed to a logic “high,” the node N13 is charged to the supply voltage VCC by the PMOS transistor MP12 and then charged to the boosted voltage VPP by the PMOS transistor MP11. Therefore, consumption of the boosted voltage VPP can be decreased.

Similarly, the second control circuit 252b can include the inverter formed by the PMOS transistor MP14 and the NMOS transistor MN12, and the delay circuit D2. When the second control signal CS2 is changed to a logic “high,” the node N14 is charged to the supply voltage VCC by the PMOS transistor MP14 and then charged to the boosted voltage VPP by the PMOS transistor MP13. Therefore, consumption of the boosted voltage VPP can be decreased.

Referring to FIG. 5, in case that the first control signal CS1 and the second control signal CS2 are changed from logic “low” to logic “high,” the voltage level of the first control signal CS1 and the second control signal CS2 are changed to the VCC and then to the VPP.

A size of the NMOS transistor MN6 can be larger than a size of the NMOS transistor MN7 and a size of the capacitor MC11 can be larger than a size of the capacitor MC12.

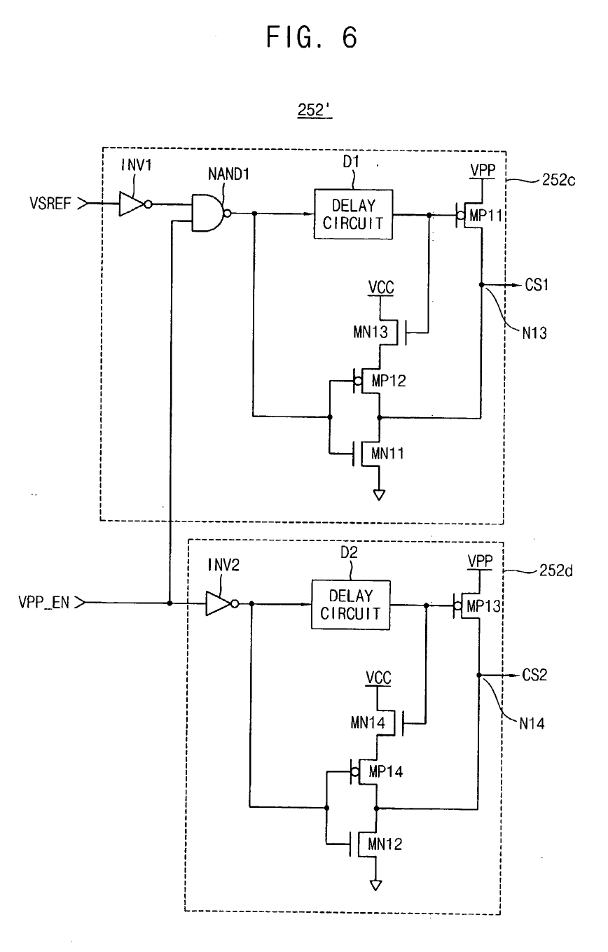

FIG. 6 is a circuit diagram illustrating an alternative example embodiment of a control signal generating circuit 252 included in the coupling circuit in FIG. 3. This embodiment can serve as one possible alternative control signal generating circuit to that of FIG. 4. Referring to FIG. 6, a control signal generating circuit 252′ can include control circuits 252c and 252d.

The control circuit 252c can include an inverter INV1, a NAND gate NAND1, a delay circuit D1, a PMOS transistor MP11, a PMOS transistor MP12, an NMOS transistor MN11 and an NMOS transistor MN13. The PMOS transistor MP12, the NMOS transistor MN11 and NMOS transistor MN13 form an inverter.

The inverter INV1 inverts the self-refresh signal VSREF. The NAND gate NAND1 performs a NAND operation with respect to the boosting enable signal VPP_EN and an output signal of the inverter INV1. The delay circuit D1 delays an output signal of the NAND gate NAND1 for a predetermined time. The PMOS transistor MP11 provides the boosted voltage VPP to the node N13 in response to an output signal of the delay circuit D1. The inverter formed by the PMOS transistor MP12, the NMOS transistor MN11 and the NMOS transistor MN13 is driven by the supply voltage VCC and inverts the output signal of the NAND gate NAND1 to be provided to the node N13. The NMOS transistor MN13 has a drain connected to the supply voltage VCC and a gate connected to an output terminal of the delay circuit D1. The PMOS transistor MP12 has a gate connected to an output terminal of the NAND gate NAND1, a source connected to a source of the NMOS transistor MN13, and a drain connected to the node N13. The NMOS transistor MN11 has a gate connected to the output terminal of the NAND gate NAND1, a source connected to a ground voltage, and a drain connected to the node N13.

The control circuit 252d can include an inverter INV2, a delay circuit D2, a PMOS transistor MP13, a PMOS transistor MP14, an NMOS transistor MN12 and an NMOS transistor MN14. The PMOS transistor MP14, the NMOS transistor MN12 and the NMOS transistor MN14 form an inverter.

The inverter INV2 inverts the boosting enable signal VPP_EN. The delay circuit D2 delays an output signal of the inverter INV2 for a predetermined time. The PMOS transistor MP13 provides the boosted voltage VPP to the node N14 in response to an output signal of the delay circuit D2. The inverter formed by the PMOS transistor MP14, the NMOS transistor MN12 and the NMOS transistor MN14 is driven by the supply voltage VCC and inverts the output signal of the inverter INV2 to be provided to the node N14. The NMOS transistor MN14 has a drain connected to the supply voltage VCC and a gate connected to an output terminal of the delay circuit D2. The PMOS transistor MP14 has a gate connected to an output terminal of the inverter INV2, a source connected to a source of the NMOS transistor MN14, and a drain connected to the node N14. The NMOS transistor MN12 has a gate connected to the output terminal of the inverter INV2, a source connected to the ground voltage, and a drain connected to the node N14.

The operation of the control signal generating circuit 252′ shown in FIG. 6 will be described as follows.

The first control circuit 252c included in the control signal generating circuit 252′ in FIG. 6 can include the inverter formed by the PMOS transistor MP12 and the NMOS transistors MN11 and MN13. In case that the first control signal CS1 is changed from a logic “low” to a logic “high,” the node N13 is charged to the supply voltage VCC by the PMOS transistor MP12 and then charged to the boosted voltage VPP by the PMOS transistor MP11. Therefore, consumption of the boosted voltage VPP can be decreased. When the output signal of the NAND gate NAND1, which is at a logic “low,” passes through the delay circuit D1, the NMOS transistor MN13 is turned off. Therefore, when the PMOS transistor MP11 is turned on and then the node N13 is charged to the boosted voltage VPP after being charged to the supply voltage VCC, the NMOS transistor MN13 electrically disconnects the node N13 from the supply voltage VCC. Thus, the NMOS transistor MN13 can function so as to prevent the boosted voltage VPP and the supply voltage VCC from being shorted.

Similarly, the second control circuit 252d can include the inverter formed by the PMOS transistor MP14 and the NMOS transistors MN12 and MN14. In case that the second control signal CS2 is changed from a logic “low” to a logic “high,” the node N14 is charged to the supply voltage VCC by the PMOS transistor MP14 and then charged to the boosted voltage VPP by the PMOS transistor MP13. Therefore, consumption of the boosted voltage VPP can be decreased. When the output signal of the inverter INV2, which is at a logic “low,” passes through the delay circuit D2, the NMOS transistor MN14 is turned off. Therefore, when the PMOS transistor MP13 is turned on and then the node N14 is charged to the boosted voltage VPP after being charged to the supply voltage VCC, the NMOS transistor MN14 electrically disconnects the node N14 from the supply voltage VCC. Thus, the NMOS transistor MN14 can function so as to prevent the boosted voltage VPP and the supply voltage VCC from being shorted.

The operation of the coupling circuit 250 having the control signal generating circuit 252′ in FIG. 6 is similar to the operation of the coupling circuit 250 having the control signal generating circuit 252 in FIG. 4, so that description will be omitted.

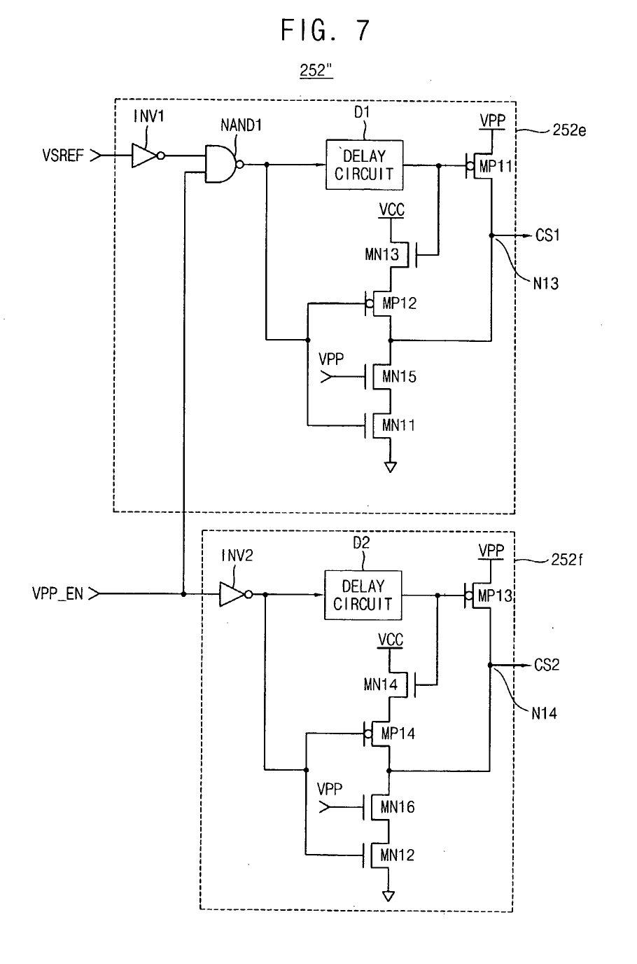

FIG. 7 is a circuit diagram illustrating another alternative example embodiment of a control signal generating circuit 252 included in the coupling circuit in FIG. 3. Referring to FIG. 7, a control signal generating circuit 252″ can include control circuits 252e and 252f.

The control circuit 252e can include an inverter INV1, a NAND gate NAND1, a delay circuit D1, a PMOS transistor MP11, a PMOS transistor MP12, an NMOS transistor MN11, an NMOS transistor MN15 and an NMOS transistor MN13. The PMOS transistor MP12, the NMOS transistor MN11, the NMOS transistor MN15 and the NMOS transistor MN13 form an inverter.

The inverter INV1 inverts the self-refresh signal VSREF. The NAND gate NAND1 performs a NAND operation with respect to the boosting enable signal VPP_EN and an output signal of the inverter INV1. The delay circuit D1 delays an output signal of the NAND gate NAND1 for a predetermined time. The PMOS transistor MP11 provides the boosted voltage VPP to the node N13 in response to an output signal of the delay circuit D1. The inverter formed by the PMOS transistor MP12, the NMOS transistor MN11, the NMOS transistor MN15 and the NMOS transistor MN13 is driven by the supply voltage VCC and inverts the output signal of the NAND gate NAND1 to be provided to the node N13. The NMOS transistor MN13 has a drain connected to the supply voltage VCC and a gate connected to an output terminal of the delay circuit D1. The PMOS transistor MP12 has a gate connected to an output terminal of the NAND gate NAND1, a source connected to a source of the NMOS transistor MN13, and a drain connected to the node N13. The NMOS transistor MN15 has a drain connected to the node N13 and a gate receiving the boosted voltage VPP. The NMOS transistor MN11 has a gate connected to the output terminal of the NAND gate NAND1, a source connected to the ground voltage, and a drain connected to a source of the NMOS transistor MN15.

The control circuit 252f can include an inverter INV2, a delay circuit D2, a PMOS transistor MP13, a PMOS transistor MP14, an NMOS transistor MN12, an NMOS transistor MN16 and an NMOS transistor MN14. The PMOS transistor MP14, the NMOS transistor MN12, the NMOS transistor MN16 and the NMOS transistor MN14 form an inverter.

The inverter INV2 inverts the boosting enable signal VPP_EN. The delay circuit D2 delays an output signal of the inverter INV2 for a predetermined time. The PMOS transistor MP13 provides the boosted voltage VPP to the node N14 in response to an output signal of the delay circuit D2. The inverter formed by the PMOS transistor MP14, the NMOS transistor MN12, the NMOS transistor MN16 and the NMOS transistor MN14 is driven by the supply voltage VCC and inverts the output signal of the inverter INV2 to be provided to the node N14. The NMOS transistor MN14 has a drain connected to the supply voltage VCC and a gate connected to an output terminal of the delay circuit D2. The PMOS transistor MP14 has a gate connected to an output terminal of the inverter INV2, a source connected to a source of the NMOS transistor MN14, and a drain connected to the node N14. The NMOS transistor MN16 has a drain connected to the node N14 and a gate receiving the boosted voltage VPP. The NMOS transistor MN12 has a gate connected to the output terminal of the inverter INV2, a source connected to the ground voltage, and a drain connected to a source of the NMOS transistor MN16.

The operation of the control signal generating circuit 252″ shown in FIG. 7 will be described as follows.

The first control circuit 252e included in the control signal generating circuit 252″ in FIG. 7 can include the inverter formed by the PMOS transistor MP12 and the NMOS transistors MN11, MN13 and MN15. In case that the first control signal CS1 is changed from a logic “low” to a logic “high,” the node N13 is charged to the supply voltage VCC by the PMOS transistor MP12 and then charged to the boosted voltage VPP by the PMOS transistor MP11. Therefore, consumption of the boosted voltage VPP can be decreased. When the output signal of the NAND gate NAND1, which is a logic “low,” passes through the delay circuit D1, the NMOS transistor MN13 is turned off. Therefore, when the PMOS transistor MP11 is turned on and then the node N13 is charged to the boosted voltage VPP after being charged to the supply voltage VCC, the NMOS transistor MN13 electrically disconnects the node N13 from the supply voltage VCC. Namely, the NMOS transistor MN13 functions so as to prevent the boosted voltage VPP and the supply voltage VCC from being shorted. The NMOS transistor MN15 has a gate receiving the boosted voltage VPP and protects the NMOS transistor MN11 from the voltage level of the node N13.

Similarly, the second control circuit 252f can include the inverter formed by the PMOS transistor MP14 and the NMOS transistors MN12, MN14 and MN16. In case that the second control signal CS2 is changed from a logic “low” to a logic “high,” the node N14 is charged to the supply voltage VCC by the PMOS transistor MP14 and then charged to the boosted voltage VPP by the PMOS transistor MP13. Therefore, consumption of the boosted voltage VPP can be decreased. When the output signal of the inverter INV2, which is at a logic “low,” passes through the delay circuit D2, the NMOS transistor MN14 is turned off. Therefore, when the PMOS transistor MP13 is turned on and then the node N14 is charged to the boosted voltage VPP after being charged to the supply voltage VCC, the NMOS transistor MN14 electrically disconnects the node N14 from the supply voltage VCC. Namely, the NMOS transistor MN14 functions so as to prevent the boosted voltage VPP and the supply voltage VCC from being shorted. The NMOS transistor MN16 has a gate receiving the boosted voltage VPP and protects the NMOS transistor MN12 from the voltage level of the node N14.

The operation of the coupling circuit 250 having the control signal generating circuit 252″ in FIG. 7 is similar to the operation of the coupling circuit 250 having the control signal generating circuit 252 in FIGS. 4 and 252′ in FIG. 6, so that description will be omitted.

As described above, the voltage boosting circuit of a semiconductor memory device according to example embodiments of the present invention can include the coupling circuit electrically coupling boosting nodes, to decrease power consumption by causing the time for charges to be shared between the boosting nodes to be different in accordance with the operating mode.

Having thus described exemplary embodiments of the present invention, it is to be understood that the invention defined by the appended claims is not to be limited by particular details set forth in the above description, as many apparent variations thereof are possible without departing from the spirit or scope thereof as hereinafter claimed. It is intended by the following claims to claim that which is literally described and all equivalents thereto, including all modifications and variations that fall within the scope of each claim.

What is claimed is:

1. A voltage boosting circuit for a semiconductor memory device, the circuit comprising:
a first precharge circuit configured to precharge a first node by using a first supply voltage;
a second precharge circuit configured to precharge a second node by using a second supply voltage;
a first capacitive element configured to boost a voltage level of the first node in response to a first pulse signal;
a second capacitive element configured to boost a voltage level of the second node in response to a second pulse signal; and
a coupling circuit configured to electrically couple the first node to the second node in response to a boosting enable signal and a self-refresh control signal.

2. The voltage boosting circuit of claim 1, wherein a boosted voltage is output at the second node, and
when the first node is electrically coupled to the second node, a time during which the voltage level of the second node becomes substantially the same as the voltage level of the first node in a self-refresh mode is longer than a time during which the voltage level of the second node becomes substantially the same as the voltage level of the first node in a normal mode.

3. The voltage boosting circuit of claim 2, wherein the first supply voltage and the second supply voltage are substantially identical to each other.

4. The voltage boosting circuit of claim 2, wherein the first supply voltage and the second supply voltage are applied from a source external to the semiconductor memory device.

5. The voltage boosting circuit of claim 2, wherein the coupling circuit comprises:
a third precharge circuit configured to precharge a third node using a third supply voltage;
a fourth precharge circuit configured to precharge a fourth node using a fourth supply voltage;
a control signal generating circuit configured to generate a first control signal and a second control signal in response to the boosting enable signal and the self-refresh control signal, and to provide the first control signal to a fifth node and the second control signal to a sixth node;
a third capacitive element configured to boost a voltage level of the third node in response to the first control signal;
a fourth capacitive element configured to boost a voltage level of the fourth node in response to the second control signal;
a first transistor configured to electrically couple the first node and the second node as a function of a voltage of the third node; and
a second transistor configured to electrically couple the first node and the second node as a function of a voltage of the fourth node.

6. The voltage boosting circuit of claim 5, wherein the first transistor is configured to turn on in the normal mode and the second transistor is configured to turn on in the normal mode and the self-refresh mode.

7. The voltage boosting circuit of claim 6, wherein a size of the first transistor is larger than a size of the second transistor.

8. The voltage boosting circuit of claim 6, wherein a size of the third capacitor is larger than a size of the fourth capacitor.

9. The voltage boosting circuit of claim 5, wherein the coupling circuit is configured to boost the voltage level of the third node and the voltage level of the fourth node using a fifth supply voltage, which is lower than the boosted voltage, and then to boost the voltage level of the third node and the voltage level of the fourth node using the boosted voltage.

10. The voltage boosting circuit of claim 9, wherein the control signal generating circuit comprises:
a first control circuit configured to generate the first control signal in response to the boosting enable signal and the self-refresh control signal; and
a second control circuit configured to generate the second control signal in response to the boosting enable signal.

11. The voltage boosting circuit of claim 10, wherein the first control circuit comprises:
a NAND gate configured to perform a NAND operation with respect to the boosting enable signal and the self-refresh control signal;
a first delay circuit connected to an output terminal of the NAND gate and configured to delay an output signal of the NAND gate for a predetermined time;
a first metal-oxide semiconductor (MOS) transistor configured to provide the boosted voltage to the fifth node in response to an output signal of the first delay circuit; and
a first inverter configured to be driven by the fifth supply voltage and configured to invert the output signal of the NAND gate to be provided to the fifth node.

12. The voltage boosting circuit of claim 11, wherein the first inverter comprises:
a first P-type MOS (PMOS) transistor having a gate connected to the output terminal of the NAND gate, a source connected to the fifth supply voltage, and a drain connected to the fifth node; and
a first N-type MOS (NMOS) transistor having a gate connected to the output terminal of the NAND gate, a source connected to a ground voltage, and a drain connected to the fifth node.

13. The voltage boosting circuit of claim 11, wherein the first inverter comprises:
a first NMOS transistor having a drain connected to the fifth supply voltage and a gate connected to an output terminal of the first delay circuit;
a first PMOS transistor having a gate connected to the output terminal of the NAND gate, a source connected to a source of the first NMOS transistor, and a drain connected to the fifth node; and
a second NMOS transistor having a gate connected to the output terminal of the NAND gate, a source connected to the ground voltage, and a drain connected to the fifth node.

14. The voltage boosting circuit of claim 11, wherein the first inverter comprises:
a first NMOS transistor having a drain connected to the fifth supply voltage and a gate connected to an output terminal of the first delay circuit;
a first PMOS transistor having a gate connected to the output terminal of the NAND gate, a source connected to a source of the first NMOS transistor, and a drain connected to the fifth node;
a second NMOS transistor having a drain connected to the fifth node and a gate configured to receive the boosted voltage; and
a third NMOS transistor having a gate connected to the output terminal of the NAND gate, a source connected to the ground voltage, and a drain connected to a source of the second NMOS transistor.

15. The voltage boosting circuit of claim 10, wherein the second control circuit comprises:
a first inverter configured to invert the boosting enable signal;
a first delay circuit connected to an output terminal of the first inverter and configured to delay an output signal of the first inverter for a predetermined time;
a MOS transistor configured to provide the boosted voltage to the sixth node in response to an output signal of the first delay circuit; and
a second inverter configured to be driven by the fifth supply voltage and invert an output signal of the first inverter to be provided to the sixth node.

16. The voltage boosting circuit of claim 15, wherein the second inverter comprises:
a first PMOS transistor having a gate connected to the output terminal of the first inverter, a source connected to the fifth supply voltage, and a drain connected to the sixth node; and
a first NMOS transistor having a gate connected to the output terminal of the first inverter, a source connected to the ground voltage, and a drain connected to the sixth node.

17. The voltage boosting circuit of claim 15, wherein the second inverter comprises:
a first NMOS transistor having a drain connected to the fifth supply voltage and a gate connected to an output terminal of the first delay circuit;
a first PMOS transistor having a gate connected to the output terminal of the first inverter, a source connected to the first NMOS transistor, and a drain connected to the sixth node; and
a second NMOS transistor having a gate connected to an output terminal of the first inverter, a source connected to the ground voltage, and a drain connected to the sixth node.

18. The voltage boosting circuit of claim 15, wherein the second inverter comprises:
a first NMOS transistor having a drain connected to the fifth supply voltage and a gate connected to an output terminal of the first delay circuit;
a first PMOS transistor having a gate connected to the output terminal of the first inverter, a source connected to a source of the first NMOS transistor, and a drain connected to the sixth node;
a second NMOS transistor having a drain connected to the sixth node and a gate receiving the boosted voltage; and
a third NMOS transistor having a gate connected to the output terminal of the first inverter, a source connected to the ground voltage, and a drain connected to a source of the second NMOS transistor.

19. The voltage boosting circuit of claim 1, further comprising a transfer circuit configured to transfer the boosted voltage to circuit blocks of the semiconductor memory device.

20. A method of boosting voltage of a semiconductor memory device comprising:
precharging a first node using a first supply voltage;
precharging a second node using a second supply voltage;
boosting a voltage level of the first node in response to a first pulse signal;
electrically coupling the first node to the second node in response to a boosting enable signal and a self-refresh control signal; and
boosting a voltage level of the second node in response to a second pulse signal.

21. The method of claim 20, further comprising:
when the first node is electrically coupled to the second node, causing a time during which the voltage level of the second node becomes substantially the same as the voltage level of the first node in a self-refresh mode to be longer than a time during which the voltage level of the second node becomes substantially the same as the voltage level of the first node in a normal mode.
